(19) United States
(12) Patent Application Publication
(10) Pub. No.: US 2012/0268162 A1
(43) Pub. Date: Oct. 25, 2012

(54) CONFIGURABLE LOGIC CELLS

(75) Inventors: Kevin Lee Kilzer, Chandler, AZ (US); Sean Steedman, Phoenix, AZ (US); Jerrold S. Zdenek, Riverside, IL (US); Vivien N. Delport, Chandler, AZ (US); Zeke Lundstrum, Chandler, AZ (US); Fanie Duvenhage, Phoenix, AZ (US)

(73) Assignee: Microchip Technology Incorporated

(21) Appl. No.: 13/449,850

(22) Filed: Apr. 18, 2012

Related U.S. Application Data
(60) Provisional application No. 61/477,754, filed on Apr. 21, 2011.

(51) Int. Cl. H03K 19/173

(52) U.S. Cl. 326/37

(57) ABSTRACT

An integrated circuit device, in accordance with embodiments as claimed includes a central processing core; and a plurality of peripherals operably coupled to the RISC CPU core. In some embodiments, the plurality of peripherals include at least one configurable logic cell peripheral having more inputs than input-output connections on the integrated circuit device. In some embodiments, the inputs include one or more inputs from one or more integrated circuit subsystems.

### CROSS-REFERENCE TO RELATED APPLICATIONS

This application claims the benefit of U.S. Provisional Application No. 61/477,754 filed on Apr. 21, 2011, entitled “Configurable Logic Cells”, which is incorporated by reference herein in its entirety. This application is related to co-pending U.S. patent application Ser. No. 13/449,687, filed on Apr. 18, 2012, entitled “Selecting Four Signals From Sixteen Inputs”; U.S. patent application Ser. No. ______, filed on ______ entitled “Configurable Logic Cells”; and U.S. patent application Ser. No. ______, filed on ______ entitled “A Logic Device For Combining Various Interrupt Sources Into A Single Interrupt Source And Various Signal Sources To Control Drive Strength”, all filed concurrently herewith and incorporated by reference in their entirety.

### BACKGROUND OF THE INVENTION

1. Field of the Invention

This invention relates to configurable logic cells and, more particularly, to a RISC processor with combinatorial logic peripherals.

2. Description of the Related Art

Most logic devices are available in a package with a single pin for each logic input and output (not counting power and ground pins). For example, a 74L500 logic gate has four instances of a 2-input, 1-output device, requiring twelve pins, and is available in a fourteen pin package including power and ground.

In a system employing a number of configurable logic cells, it is often required that software reads the outputs of all cells at about the same time. Since the cells are instantiated independently, the output register (bit) for each cell is in a different register, and requires the central processing unit (CPU) to perform a number of read operations to determine the state of each bit. Inherently, this means that the cells are never sampled at the same time, and could in fact be samples at widely spaced intervals or perhaps in different orders, and this can at times produce misleading results.

Configurable logic cells of microcontrollers are versatile, but, having only a single logic function and/or state variable, can only be applied to a limited class of applications. FPGAs and PLDs provide configurable logic cells that are generally based on D flip-flop technology. While this is adequate for general purpose use and automated logic configuration, it does not always lead to a minimal circuit implementation solution.

### SUMMARY OF THE INVENTION

These and other drawbacks in the prior art are overcome in large part by a system and method according to embodiments of the present invention.

An integrated circuit device, in accordance with embodiments as claimed includes a central processing core; and a plurality of peripherals operably coupled to the central processing core. In some embodiments, the plurality of peripherals include at least one configurable logic cell peripheral having more inputs than input-output connections on the integrated circuit device. In some embodiments, the inputs include one or more inputs from one or more integrated circuit subsystems.

In some embodiments, the inputs include at least one input from at least one other configurable logic peripheral. In some embodiments, the integrated circuit device includes a single microprocessor register configured for reading outputs of a plurality of configurable logic cells. In some embodiments, at least two of configurable logic cells are cascaded.

### BRIEF DESCRIPTION OF THE DRAWINGS

The present invention may be better understood, and its numerous objects, features, and advantages made apparent to those skilled in the art by referencing the accompanying drawings. The use of the same reference symbols in different drawings indicates similar or identical items.

FIG. 1 illustrates an exemplary integrated circuit including a configurable logic cell.

FIG. 2 illustrates an exemplary data and address lines in an integrated circuit including a configurable logic cell.

FIG. 3 illustrates an exemplary module including a configurable logic cell.

FIG. 4A and FIG. 4B illustrate software control and configuration of a configurable logic cell.

FIG. 5A and FIG. 5B illustrate exemplary logic functions for a configurable logic cell that replaces two statically configured functions with a single, software-controlled function.

FIG. 6A-FIG. 6D illustrate logic function combinatorial options for an exemplary configurable logic cell.

FIG. 7A-7D illustrate logic function state options for an exemplary configurable logic cell.

FIG. 8 illustrates an exemplary JK flip flop application and timing implemented with an exemplary configurable logic cell.

FIG. 9 is a diagram of an exemplary integrated circuit pin configuration.

FIG. 10 illustrates exemplary output register usage for a plurality of configurable logic cells.

FIG. 11 illustrates exemplary cascading of configurable logic cells.

### DETAILED DESCRIPTION

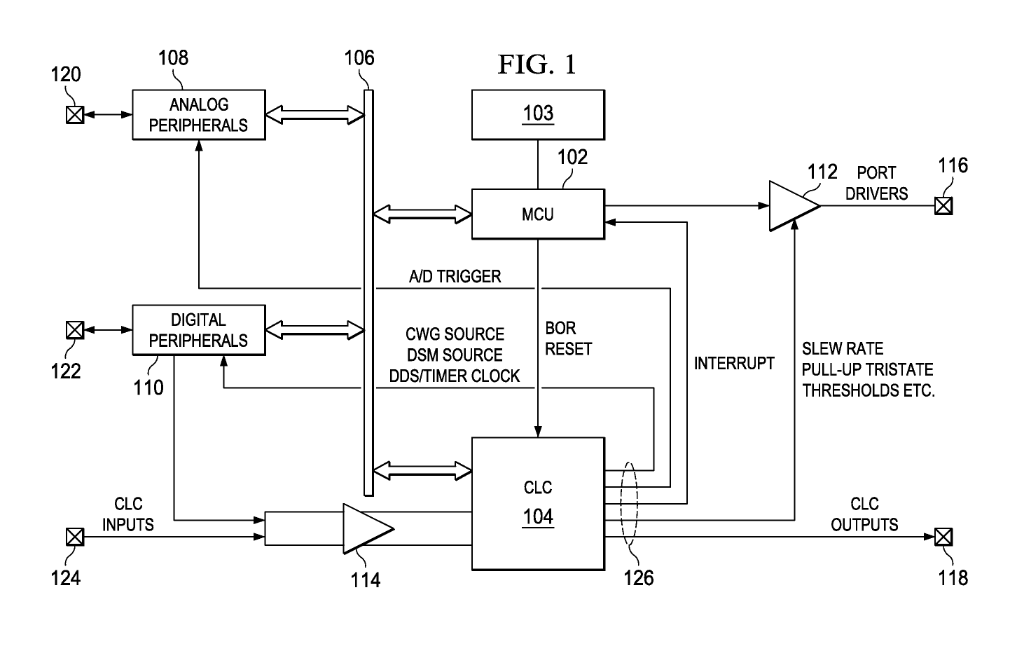

Turning now to the drawings and, with particular attention to FIG. 1, a diagram of a processor 100 according to an embodiment of the present invention is shown. The processor 100 includes a processor core (MCU) 102, which may be embodied as a RISC core. The processor core 102 couples via a bus 106 to one or more on-chip peripheral devices, such as analog peripherals 108 and digital peripherals 110.

In addition, as will be explained in greater detail below, the processor 100 further includes one or more configurable logic cells (CLC) 104, functioning as peripheral devices and coupled to the bus 106. That is, the configurable logic cells 104 are addressable like other peripheral devices and provide logic functions for the system. These can include, for example, AND, OR, XOR functions, and D, JK, and SR storage.

The processor 100 further includes one or more input and/or outputs 116, 118, 120, 122, 124, and associated port drivers, input controls 114, etc.

In the embodiment illustrated, the configurable logic cell 104 receives inputs from external pin 124, digital peripherals 110, and a reset from the processor core 102. These can include, for example, CWG source, DSM source, and DDS/Timer clock inputs. In general, inputs can come from I/O pins, register bits, other peripherals, and internal clocks.

In addition, the configurable logic cell 104 can provide digital outputs to one or more of the analog peripherals 108, the digital peripherals 110, and the processor core 102. Additional outputs (such as slew rate, pull-up tristate thresholds, etc.) can be provided to port drivers 112, while others can be provided to external pins 118.

Thus, in general, the configurable logic cell 104 can receive inputs from any subsystem such as a digital peripheral, I/O port, or internal status bits, or reset signals, including for example, oscillator output, system clocks, etc., and provides outputs to I/O pins, peripherals, a processor core interrupt, I/O port control functions, status signals, system clock, and even to other configurable logic cells (not shown).

As noted above, in some embodiments, the configurable logic cell 104 is addressed like other peripheral devices and may be configured at run-time. In some embodiments, the configurable logic cell 104 may be configured at run time using one or more special function registers (not shown). Thus, the configurable logic cell 104 is fully integrated into the processor address and data bus. Configuration can be applied statically or updated in real time based on the needs of the application.

In some embodiments, configuration of the configurable logic cell 104 can come from software registers or non-volatile memory. In some embodiments, the memory may be read and data transferred to configuration registers. In others, the memory may be statically connected for configuration (as in generic logic arrays/programmable logic arrays (GAL/PAL)). Further, in some embodiments, after an initial configuration, software may update the configuration.

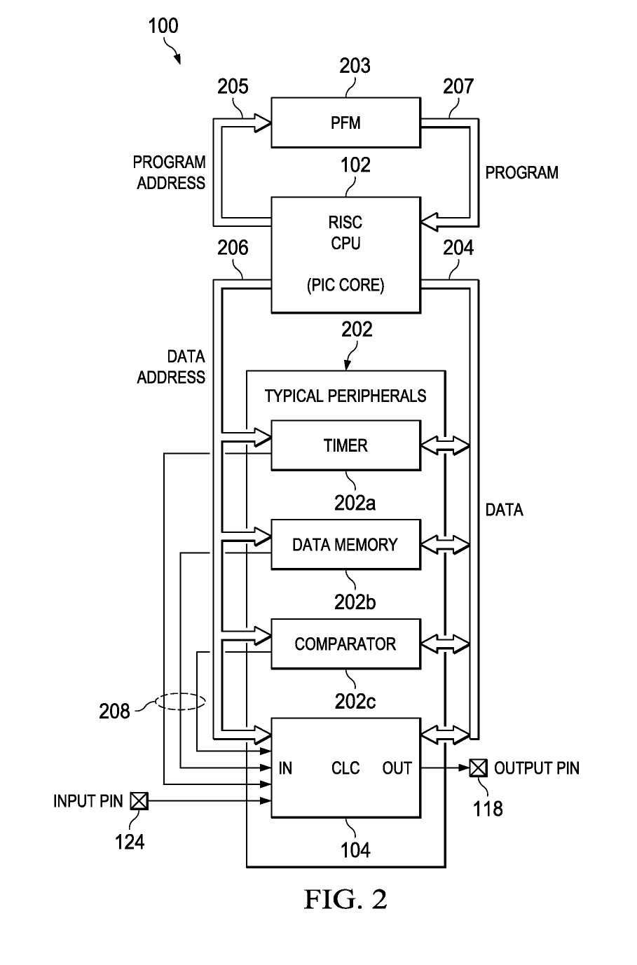

As such, in some embodiments, system signals and I/O signals are routed to the configurable logic cell 104, as shown in FIG. 2. The configurable logic cell 104 then performs the configured logic and provides an output. In particular, shown in FIG. 2 is processor 100 including processor core 102, a program flash memory 203, and peripherals 202. The program flash memory 203 couples via program address lines/bus 205 and program data lines/bus 207 to the processor core 102.

In the example illustrated, the peripherals include a timer 202a, data memory 202b, a comparator 202c, and the configurable logic cell 104. The peripherals couple to the processor core 102 by data address lines/bus 206 and data lines/bus 204. The configurable logic cell 104 may receive further individual inputs from the peripherals 208 or from an input pin 124. Thus, software and other peripherals can supply inputs to the configurable logic cell 104. The configurable logic cell 104 performs a configured logic operation and provides an output 312.

As noted above, the configurable logic cell implements one or more logic functions and can do so independently of the status of the processor core, e.g., while the processor core is in a sleep or debug mode.

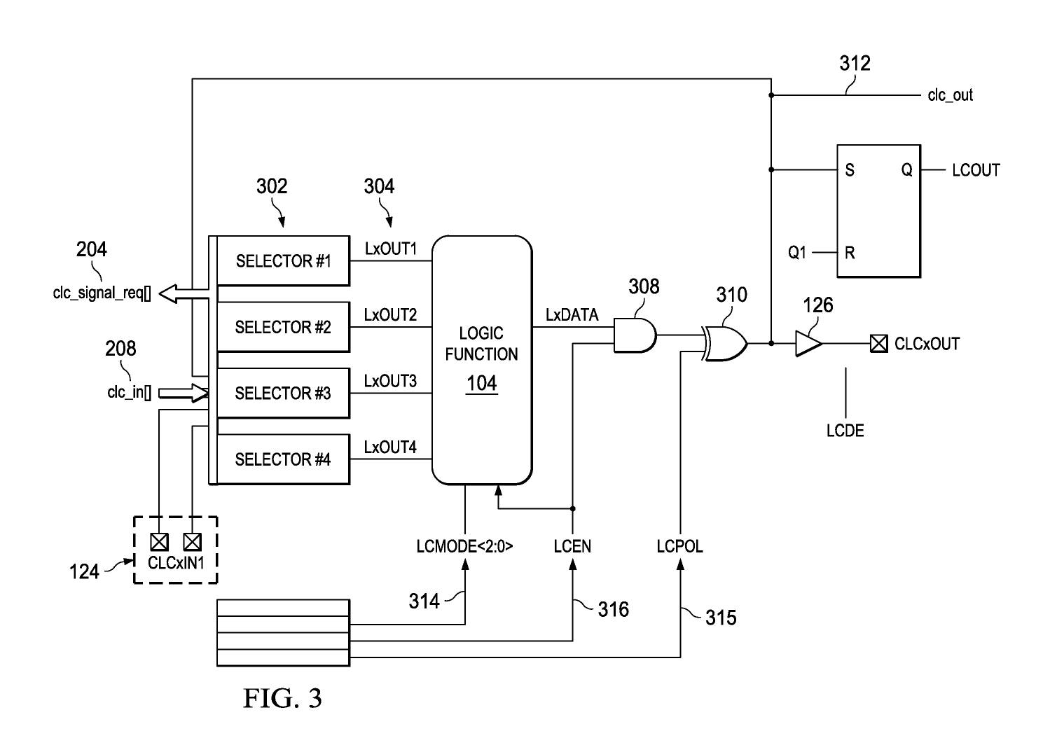

FIG. 3 illustrates the configurable logic cell environment according to one embodiment more particularly. Configurable logic cell 104 receives four channel inputs 304 LxOUT1, LxOUT2, LxOUT3, and LxOUT4 from a plurality of selectors 302. Inputs to the selectors 302 can come from signals 208 and I/O 124. In some embodiments, the selectors are multiplexers and/or configurable gates. For example, in some embodiments, the selectors 302 can reduce the number of inputs clc_in 208 from eight to four 304 to drive one of eight selectable single-output functions. Further details on particular implementations of the selectors 302 may be found in commonly-assigned patent application Ser. No. ______, titled “Selecting Four Signals from Sixteen Inputs,” filed Apr. 17, 2012, which is hereby incorporated by reference in its entirety as if fully set forth herein.

In the example illustrated, the configurable logic cell 104 receives control inputs LCMODE<2:0> 314 and LCEN 316 from control registers (not shown). The output LxDATA of the configurable logic cell 104 is ANDed with the LCEN input 316. The output of AND gate 308 is XORed with LCPOL a control signal from a control register (not shown) and then output as CLCxOUT, all of which are explained in greater detail below.

As noted above, embodiments allow for real time configuration of the configurable logic cell. That is, configuration is provided through registers accessible from the microprocessor and can be updated based, for example, on external inputs, time of day, temperature of the system, coincidence with other events, or commands from a remotely controlling host.

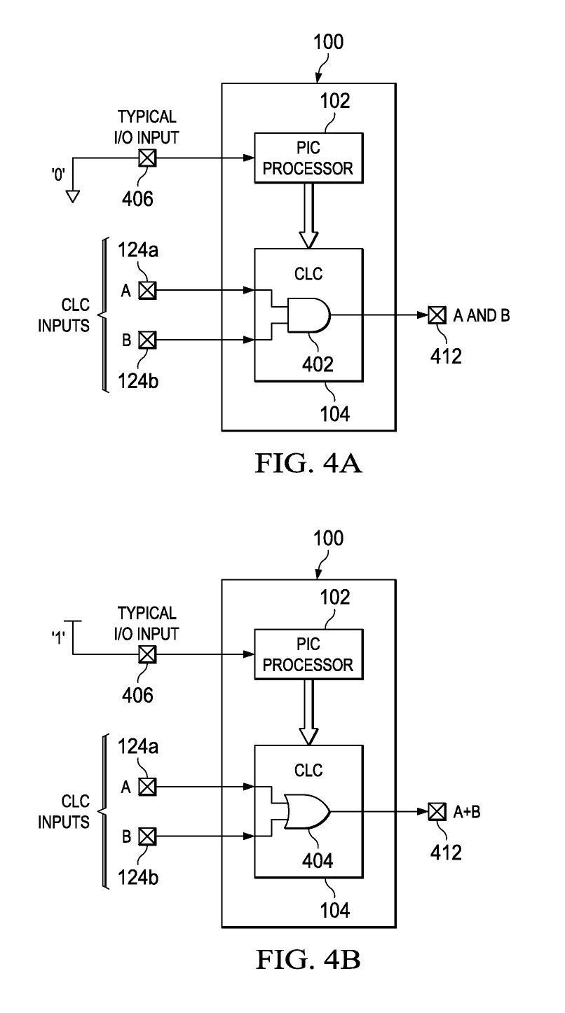

FIG. 4A and FIG. 4B schematically illustrate such operation. In particular, shown is processor 100 including processor core 102 and configurable logic cell 104. The processor 100 has an I/O input 406 to the processor core 102 and a pair of inputs 124a, 124b to the configurable logic core 104. The configurable logic cell 104 outputs to pin 412.

In operation, the state of the I/O pin 406 can be used to set the configurable logic core function. In the example illustrated, when the logic state of the I/O input 406 is “0”, the processor core 102 writes to one or more registers (such as the L×Mode register 314 of FIG. 3) to cause the configurable logic cell 104 to implement an AND function 402, so that the outputs on pin 412 is the logical AND of inputs A 124a and B 124b (AB). In contrast, when the logic state of the I/O input 406 is “1”, the processor core 102 writes to one or more registers to cause the configurable logic cell 104 to implement an OR function 404, so that the output on pin 412 is the logical OR of inputs A 124a and B 124b (A+B). As can be appreciated, once the functions are set, the configurable logic cell 104 implements the configured function regardless of the functioning of the processor core 102.

Advantageously, the configurable logic cell 104 of embodiments of the present invention allows for dynamic configuration and direct access to software, allowing software to reconfigure individual gates and inverters while the system is running That is, the configurable logic cell of embodiments of the invention allows real-time software access to internal configuration and signal paths, without requiring a microprocessor interface.

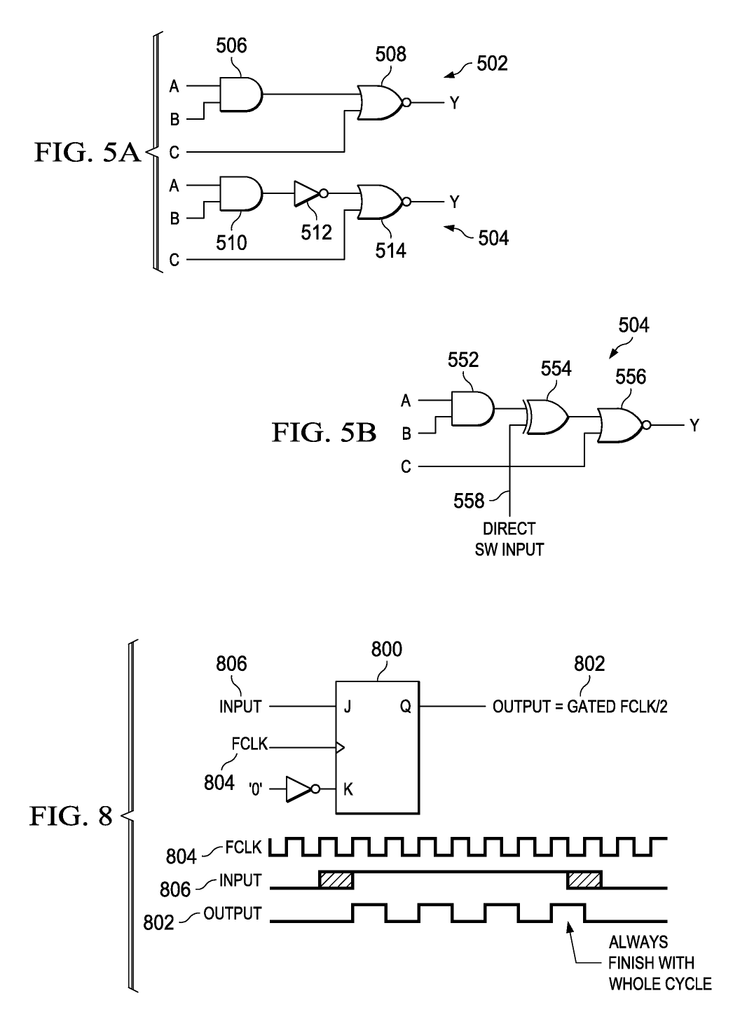

For example, as shown in FIG. 5A, a static configuration of a microprocessor interface for implementing the two functions ((A*B)+C)′ and ((A*B)'+C)′ requires two versions 502, 504, including AND gates 506, 510, NOR gates 508, 514, and inverter 512.

In contrast, an exemplary configurable logic cell 104 for implementing the functions is shown in FIG. 5B. The configurable logic cell 104 includes AND gate 552, XOR gate 554, and NOR gate 556. Inputs A and B are provided to AND gate 552, while input C is provided to the NOR gate 556. The output of the AND gate 552 is provided to the XOR gate 554, while the XOR gate 554 provides its output to the input of NOR gate 556. In addition, a direct software (SW) input 558 (e.g., from a control register) is provided to the input of the XOR gate 554. In this way, both functions of circuits 502, 504 are implemented using a single circuit and yet allowing direct software control.

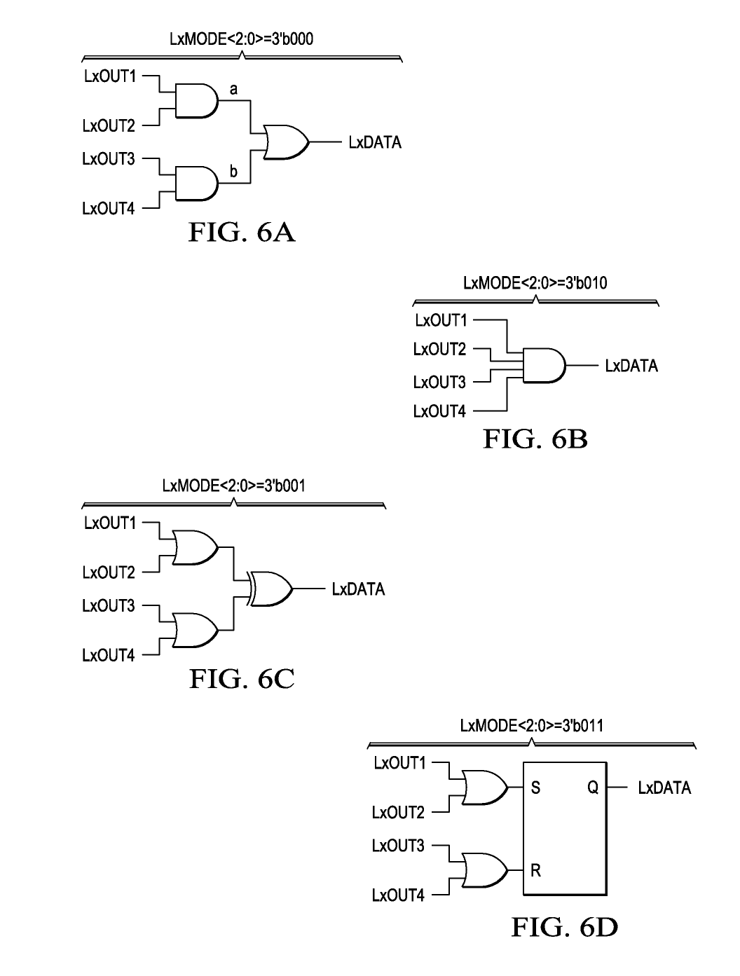

Exemplary combinatorial options for a particular four-input configurable logic cell are shown in FIG. 6A-6D. More particularly, in some embodiments, a LxMODE<2:0> configuration register 314 (FIG. 3) defines the logic mode of the cell. When LxMODE=000, the configurable logic cell implements and AND-OR function. When LxMODE=001, the cell implements an OR-XOR function. When LxMODE=010, the cell implements an AND; when LxMODE=011, the cell is an RS latch.

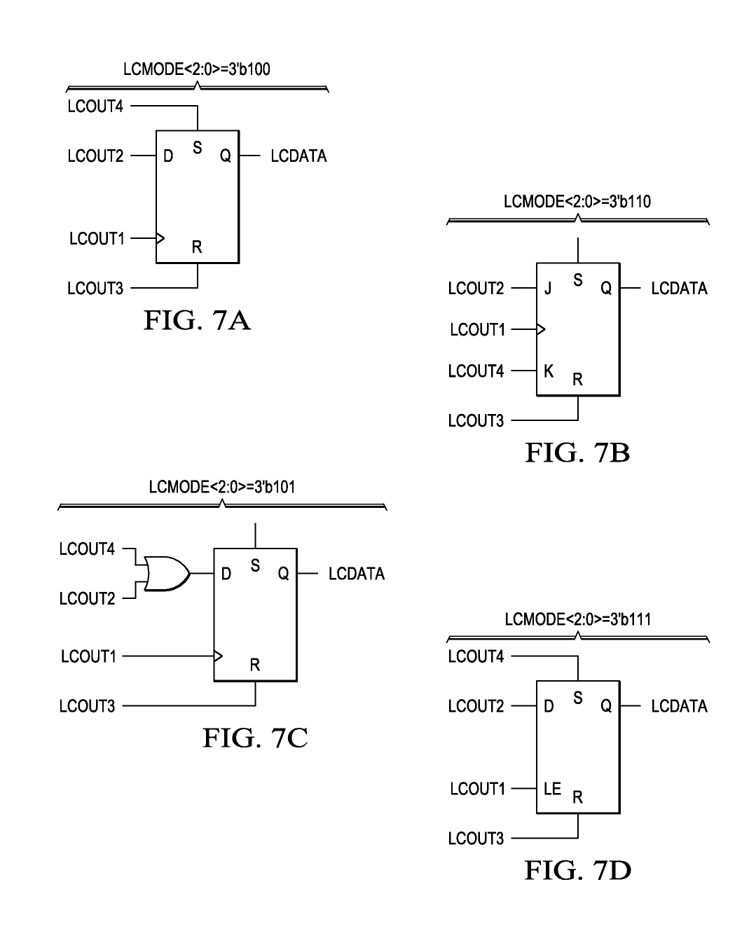

Correspondingly, the configurable logic cell 104 may incorporate a plurality of state logic functions. These are shown with reference to FIG. 7A-7D. The state functions include both D (FIG. 7A) and JK flipflops (FIG. 7B) with asynchronous set (S) and Reset (R). Input channel 1 (LCOUT1) provides a rising edge clock. If a falling edge is required, channel 1 (LCOUT1) can be inverted in the channel logic (not shown). Input channel 2 (LCOUT2), and sometimes channel 4 (LCOUT4), provide data to the register or latch inputs.

When LCMODE=100, the cell implements a one input D flipflop with S and R. When LCMODE=101, the cell implements a two input D flipflop with R. When LCMODE=110, the cell implements a JK flipflop with R. When LCMODE=111, the cell implements a one input transparent latch with S and R (The output Q follows D while LE is low and holds state while LE is high).

FIG. 8 illustrates an example operation of a JK flip-flop in accordance with embodiments of the invention. In particular, shown is a clock gating example including a JK flip flop 800, with input 806, output 802, and clock 804. The output 802 is a gated FCLK/2.

The JK flipflop can be configured according to FIG. 7B, with the clock at LCOUT1, J input at LCOUT2, and K input (inverted) at LCOUT4. As can be seen, the output 802 always includes a whole number of cycles. It is noted that other logic and state functions can be implemented. Thus, the figures are exemplary only.

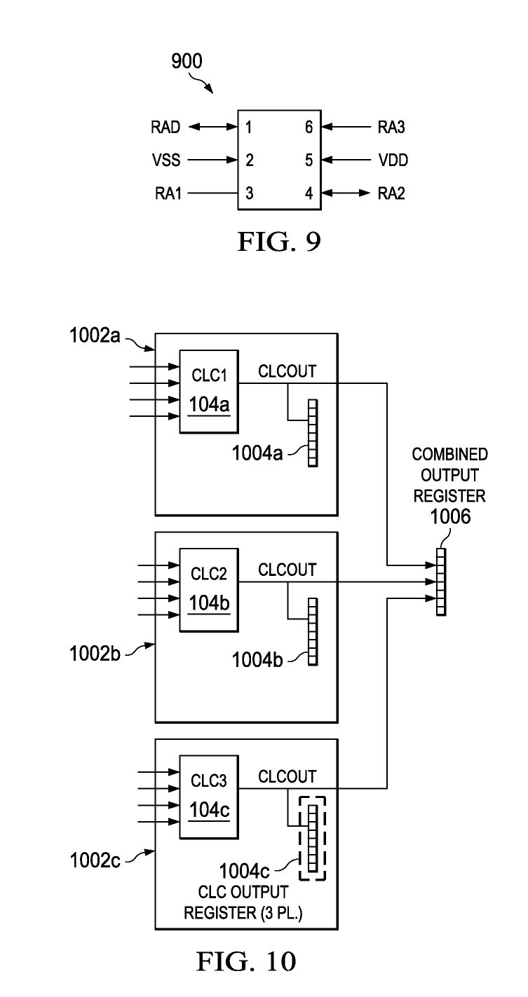

As noted above, each configurable logic cell 104 has four inputs selectable from a constellation of eight available signals, and one output, although other numbers of signals and inputs are possible. In some embodiments, however, the integrated circuit package includes only four input-output pins. That is, the integrated circuit package includes one pin for output and three for input. This is shown by way of example in FIG. 9, integrated circuit 900 includes pins RA0, RA1, RA2, RA3, Vss and Vdd. RA0-RA2 may be inputs, for example, and RA3 may be the output. Other inputs to the configurable logic cell 104 come from other peripherals on the internal data bus. In some embodiments, in which the integrated circuit includes more than one peripheral logic cell, inputs can come from other peripheral logic cells, as will be discussed in greater detail below.

More particularly, in implementations including more than one peripheral logic cell 104, it is desirable to be able to read multiple cell outputs substantially simultaneously. Consequently, in accordance with embodiments of the present invention, a combined output register may be provided. This is shown in FIG. 10, which illustrates three configurable logic units 1002a, 1002b, 1002c. It is noted that more or fewer than three may be provided. Thus, the figures are exemplary only.

Each configurable logic unit 1002a, 1002b, 1002c includes a configurable logic cell 104a, 104b, 104c, respectively. Each further includes an output CLCOUTA, CLCOUTB, CLCOUTC, respectively. In implementations in which only one configurable logic cell is employed, the output is provided to an associated output register 1004a, 1004b, 1004c, respectively.

However, when more than one configurable logic cell is in use, the outputs are provided to the common register 1006, outside the configurable logic unit instances. By providing the combined output register 1004 outside the instances of each of the logic units, their combined outputs may be read substantially simultaneously.

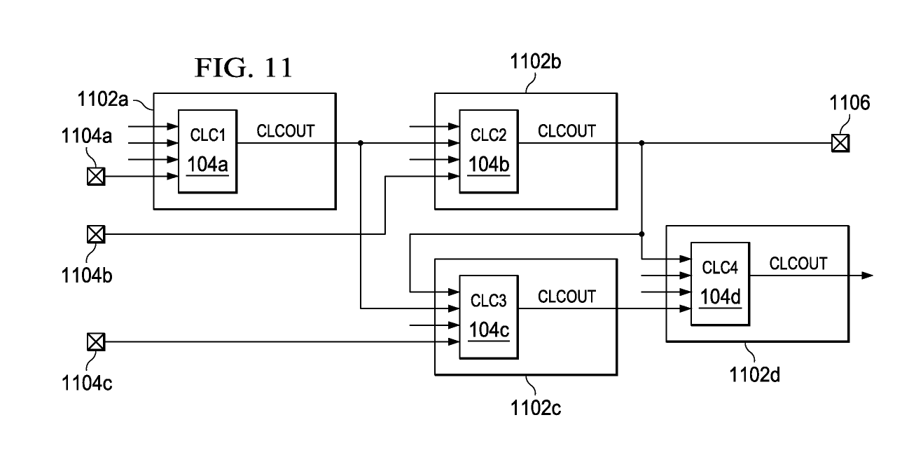

In addition, by providing multiple configurable logic cells having inputs other than external pins, the cells can be cascaded to create complex combinations. This is shown by way of example in FIG. 11.

In particular, shown in FIG. 11 is a system 1100 including a plurality of configurable logic units 1102a, 1102b, 1102c, 1102d, each including a corresponding configurable logic cell 104a, 104b, 104c, 104d, respectively. As shown, the configurable logic cell 104a provides its output to configurable logic cell 104b and 104c, while configurable logic cell 104b provides outputs to an external pin 1106 as well as to inputs of configurable logic cell 104c and configurable logic cell 104d. In addition, the configurable logic cell 104d provides its output to a output line, e.g., to another peripheral or to the processor core.

As can be seen each of the configurable logic cells 104a, 104b, 104c, 104d has four inputs and can receive input signals from input pins 1104a, 1104b, 1104c, from other configurable logic cells, or from other on-chip and peripheral devices.

While specific implementations and hardware/software configurations for the mobile computing device have been illustrated, it should be noted that other implementations and hardware configurations are possible and that no specific implementation or hardware/software configuration is needed. Thus, not all of the components illustrated may be needed for the mobile computing device implementing the methods disclosed herein.

As used herein, whether in the above description or the following claims, the terms “comprising,” “including,” “carrying,” “having,” “containing,” “involving,” and the like are to be understood to be open-ended, that is, to mean including but not limited to. Only the transitional phrases “consisting of” and “consisting essentially of,” respectively, shall be considered exclusionary transitional phrases, as set forth, with respect to claims, in the United States Patent Office Manual of Patent Examining Procedures.

Any use of ordinal terms such as “first,” “second,” “third,” etc., in the claims to modify a claim element does not by itself connote any priority, precedence, or order of one claim element over another, or the temporal order in which acts of a method are performed. Rather, unless specifically stated otherwise, such ordinal terms are used merely as labels to distinguish one claim element having a certain name from another element having a same name (but for use of the ordinal term).

The above described embodiments are intended to illustrate the principles of the invention, but not to limit the scope of the invention. Various other embodiments and modifications to these preferred embodiments may be made by those skilled in the art without departing from the scope of the present invention.

What is claimed is:

1. An integrated circuit device, comprising:
a central processing core;
a plurality of peripherals operably coupled to the central processing core, the plurality of peripherals including at least one configurable logic cell peripheral, the at least one configurable logic peripheral having more inputs than input-output connections on the integrated circuit device.

2. An integrated circuit device in accordance with claim 1, said inputs including one or more inputs from one or more integrated circuit subsystems.

3. An integrated circuit device in accordance with claim 1, said inputs including at least one input from at least one other configurable logic peripheral.

4. An integrated circuit device in accordance with claim 1, further including a single microprocessor register configured for reading outputs of a plurality of configurable logic cells.

5. An integrated circuit device in accordance with claim 4, wherein at least two of the at least one configurable logic cells are cascaded.

6. An integrated circuit device including a predetermined number of input-output connections, comprising:
a processor core;
a plurality of configurable logic peripherals operably coupled to the processor core, each of the plurality of configurable logic peripherals having a number of inputs greater than the predetermined number of input-output connections.

7. An integrated circuit device in accordance with claim 6, said inputs including one or more inputs from one or more integrated circuit subsystems

8. An integrated circuit device in accordance with claim 6, said inputs including one or more inputs from one or more others of the plurality of configurable logic peripherals.

9. An integrated circuit device in accordance with claim 6, further including a single microprocessor register configured for reading outputs of the plurality of configurable logic peripherals.

10. An integrated circuit device in accordance with claim 9, wherein at least two of the plurality of configurable logic peripherals are cascaded.

11. An integrated circuit device, comprising:
a central processing core;
a plurality of peripherals operably coupled to the central processing core, the plurality of peripherals including at least one configurable logic cell peripheral, the at least one configurable logic peripheral having more inputs than input-output connections on the integrated circuit device.

12. An integrated circuit device in accordance with claim 11, said inputs including one or more inputs from one or more integrated circuit subsystems.

13. An integrated circuit device in accordance with claim 11, said inputs including at least one input from at least one other configurable logic peripheral.

14. An integrated circuit device in accordance with claim 11, further including a single microprocessor register configured for reading outputs of a plurality of configurable logic cells.

15. An integrated circuit device in accordance with claim 13, wherein at least two of the at least one configurable logic cells are cascaded.
